(19) United States
(12) Patent Application Publication
(10) Pub. No.: US 2025/0292072 A1
(43) Pub. Date: Sep. 18, 2025

(54) NEUROMORPHIC COMPUTING DEVICE USING SPIKING NEURAL NETWORK AND OPERATING METHOD THEREOF

(71) Applicant: SAMSUNG ELECTRONICS CO., LTD., Suwon-si (KR)

(72) Inventors: Wanki KIM, Suwon-si (KR); Youngnam HWANG, Suwon-si (KR)

(73) Assignee: SAMSUNG ELECTRONICS CO., LTD., Suwon-si (KR)

(21) Appl. No.: 18/824,434

(22) Filed: Sep. 4, 2024

(30) Foreign Application Priority Data
Mar. 18, 2024 (KR) 10-2024-0037001

(51) Int. Cl. G06N 3/049

(52) U.S. Cl. CPC G06N 3/049

(57) ABSTRACT

A neuromorphic computing device according to the present disclosure may have a plurality of artificial neurons connected to a synapse array, and each of the plurality of artificial neurons may include: a ferroelectric transistor having a gate connected to a first node, and connected between a power terminal and a second node configured to output an output spike, a first input transistor having a gate configured to receive a first input spike, and connected between a first input power terminal and the first node, a second input transistor having a gate configured to receive a second input spike, and connected between a second input power terminal and the first node, an adjustment transistor having a gate receiving an adjustment voltage and connected between the second node and ground terminal, and a reset transistor having a gate receiving a reset voltage, and connected between the first node and ground terminal.

### CROSS-REFERENCE TO RELATED APPLICATION(S)

This application claims benefit of priority to Korean Patent Application No. 10-2024-0037001 filed on Mar. 18, 2024, in the Korean Intellectual Property Office, the disclosure of which is incorporated herein by reference in its entirety.

### BACKGROUND

The present disclosure relates to a neuromorphic computing device using a spiking neural network and an operating method thereof.

In general, a Spiking Neural Network (SNN) may be a type of artificial neural network modeled after biological neural networks. This network may operate by mimicking the way biological neurons spike. Each neuron may generate electrical signals at regular intervals, and these signals may be transmitted through connections with other neurons. SNNs may have several important features that distinguish them from conventional artificial neural networks. Firstly, SNNs may operate by considering temporal information. The timing and intervals of neuron spikes may play a crucial role in information processing. Secondly, SNNs may use event-driven processing, which means they may activate only when an event occurs. This may allow for efficient use of power and computational resources, as only activated neurons may participate in computation. Thirdly, the strength of synapses in SNNs may vary over time. This may effectively regulate synaptic strength to improve learning and memory functions. Fourthly, SNNs may integrate input signals over time, and neurons may spike only when a threshold is exceeded. This may enable the processing of changes in input patterns and temporal characteristics. SNNs may be applied in various fields such as sensor data processing, pattern recognition, and temporal information processing.

### SUMMARY

An aspect of the present disclosure is to provide a novel neuromorphic computing device and an operating method thereof.

An aspect of the present disclosure is to provide a neuromorphic computing device connected to an excitatory synapse and an inhibitory synapse and an operating method thereof.

An aspect of the present disclosure is to provide a neuromorphic computing device for adjusting a firing rate and an operating method thereof.

A neuromorphic computing device according to an example embodiment of the present disclosure may have a plurality of artificial neurons connected to a synapse array, and each of the plurality of artificial neurons may include: a ferroelectric transistor having a first gate connected to a first node, the ferroelectric transistor being connected between a power terminal configured to receive a power supply voltage and a second node configured to output an output spike; a first input transistor having a second gate configured to receive a first input spike, the first input transistor being connected between a first input power terminal configured to receive a first input power supply voltage and the first node; a second input transistor having a third gate configured to receive a second input spike, the second input transistor being connected between a second input power terminal configured to receive a second input power supply voltage and the first node; an adjustment transistor having a fourth gate configured to receive an adjustment voltage, the adjustment transistor being connected between the second node and a ground terminal; and a reset transistor having a fifth gate configured to receive a reset voltage, the reset transistor being connected between the first node and the ground terminal.

A neuromorphic computing device according to another example embodiment of the present disclosure may include: a synapse array, wherein the synapse array comprises excitatory synapses having first ferroelectric transistors connected between excitatory bitlines and excitatory source lines, and inhibitory synapses having second ferroelectric transistors connected between inhibitory bitlines and inhibitory source lines are arranged alternately; a pre-synaptic neuron circuit, wherein the pre-synaptic neuron circuit is connected to wordlines, and wherein the pre-synaptic neuron circuit is configured to provide corresponding input spikes to the wordlines, the wordlines being connected to gates of the first ferroelectric transistors and the second ferroelectric transistors; a bitline driver configured to provide a first bitline voltage to the excitatory bitlines and to provide a second bitline voltage to the inhibitory bitlines; and artificial neurons configured to: receive an excitatory input spike from any one of the excitatory source lines, receive an inhibitory input spike from any one of the inhibitory source lines, and output an output spike by performing a Leaky Integration-and-Fire (LIF) operation.

An operating method of a neuromorphic computing device having connected to excitatory synapses and inhibitory synapses according to an example embodiment of the present disclosure may include: training input spikes through the excitatory synapses and the inhibitory synapses; and adjusting firing rates of the artificial neurons; and training output spikes of the artificial neurons according to the adjusted firing rate.

A neuromorphic computing device according to an example embodiment may include: a plurality of stacked layers comprising transistors, wherein each layer of the plurality of stacked layers may include first ferroelectric transistors connected between an excitatory bitline and an excitatory source line, and second ferroelectric transistors connected between an inhibiting bitline and an inhibiting source line; a bitline driver configured to provide bitline voltages to the excitatory bitline and the inhibiting bitline; and an artificial neuron connected to the excitatory source line and the inhibiting source line, wherein the artificial neuron may receive a first input spike through the excitatory source line and a second input spike received through the inhibiting source line, and the artificial neuron may output an output spike by performing a Leaky Integration-and-Fire (LIF) operation.

A neuromorphic computing device and an operating method thereof according to an example embodiment of the present disclosure may increase model flexibility by enabling connection between an excitatory synapse and an inhibitory synapse.

A neuromorphic computing device and an operating method thereof according to an example embodiment of the present disclosure may increase model flexibility by improving a firing rate control method.

A neuromorphic computing device and an operating method thereof according to an example embodiment of the present disclosure may reduce a chip area using 3D stacking. Additionally, the neuromorphic computing device of the present disclosure may increase model flexibility through flexible neuron settings.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating a function of an artificial neuron according to an embodiment of the present disclosure;

FIG. 2 is a block diagram illustrating a spiking neuron of a SNN according to an embodiment of the present disclosure;

FIG. 3 is an exemplary block diagram illustrating a Ferroelectric Field Effect Transistor-based (FeFET-based) spiking neuron circuit according to an embodiment of the present disclosure;

FIG. 4 is an exemplary diagram illustrating a neuromorphic computing device according to an embodiment of the present disclosure;

FIG. 5 is an exemplary diagram illustrating an artificial neuron according to an embodiment of the present disclosure;

FIG. 6 is an exemplary process illustrating a transmission of spikes for layers in a SNN according to an embodiment of the present disclosure;

FIG. 7 is an exemplary signal diagram illustrating a timing of obtaining an output spike by training an input spike in an SNN according to an embodiment of the present disclosure;

FIGS. 8A and 8B are exemplary diagrams illustrating a firing rate control according to an embodiment of the present disclosure;

FIG. 9 is an exemplary diagram illustrating a neuromorphic computing device according to an embodiment of the present disclosure;

FIG. 10 is an exemplary diagram illustrating a flexible artificial neuron setting for layers according to the embodiment in FIG. 9;

FIG. 11 is an exemplary flexible artificial neuron setting for stacked layers;

FIG. 12 is a flowchart illustrating an operation of a neuromorphic computing device according to an embodiment of the present disclosure;

FIG. 13 is a schematic view illustrating a spiking neural network according to an embodiment of the present disclosure; and

FIG. 14 is an exemplary diagram illustrating an electronic device according to an embodiment of the present disclosure.

### DETAILED DESCRIPTION

Hereinafter, the content of the present disclosure will be described clearly and in detail using the accompanying drawings so that a person skilled in the art may easily implement the present disclosure.

Neuromorphic computing may generally be the construction of computer systems that mimic the operational principles of neurons and synapses in the human brain. It may use Artificial Neural Networks (ANN) to process and store information. The brain may have the ability to process large amounts of information simultaneously. Neuromorphic computing may operate by imitating this parallel processing capability. The brain may efficiently use energy to handle highly complex tasks. By being designed to mimic this energy efficiency, neuromorphic computing may save energy compared to traditional computing.

Neuromorphic computing may create systems with learning abilities and flexibility, enabling them to handle various tasks instead of being limited to specific operations. This field may receive significant attention in machine learning and artificial intelligence, and it may be applied in diverse areas such as pattern recognition, speech recognition, image processing, and autonomous driving.

Neuromorphic computing may largely include the Analog MAC (Multiply-and-Accumulate) method and the SNN (Spiking Neural Network) method. The Analog MAC method may be closer to an NPU (Neural Processing Unit). The SNN method may be closer to brain operation. The main components of SNNs may include artificial synapses and artificial neurons, which may be implemented using various memory devices.

The present disclosure may disclose an artificial neuron based on FeFET (Ferroelectric Field Effect Transistor) applicable to SNN implementation. In particular, the present disclosure may disclose architectures based on FeFET synapse arrays and architectures capable of three-dimensional stacking using FeMBCFET (Ferroelectric Multi-Bridge Channel Field Effect Transistor) synapses.

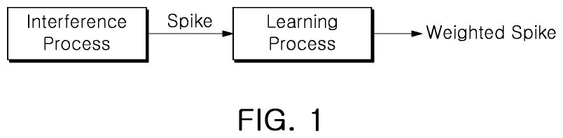

FIG. 1 is a view illustrating a function of an artificial neuron. An artificial neuron may receive an input signal, may multiply the input signal by weights, and may convert results thereof through an activation function, thereby generating an output. In this manner, the artificial neuron may model and learn complex patterns and relationships. As an example, the function of spiking neurons in the SSN includes reasoning and learning processes. An inference process may accumulate input and may perform spiking if the input exceeds a reference value, thereby outputting spikes. The learning process may update weights of a corresponding synapse according to a time difference between an input spike and an output spike.

An artificial neuron refers to electronic devices manufactured to mimic the behavior of neurons. In order to improve computational performance and integration, some neuron elements mimic the simplest model, a Leaky Integration-and-Fire (LIF) operation. The LIF operation gradually integrates signals according to a pulse input, and allows the signals to be leaky again when there is no input and performs spiking on strong spike signals when the signals exceed a threshold voltage during operation.

Ferroelectrics are materials that are widely used in memory elements. Ferroelectrics do not simply have two polarization states, and since partial polarization occurs depending on the accumulation of the input signals, ferroelectrics are suitable for application in neuron elements using accumulation of the input signals. In neurons, there are not only excitatory connections in which membrane potential accumulates according to the input, but also inhibitory connections in which spiking is suppressed by attenuating the membrane potential. When a neural network is configured by connecting neurons, the behavior of neurons may be more easily controlled through the inhibitory connections, thereby greatly improving the operational efficiency of an entire neural network.

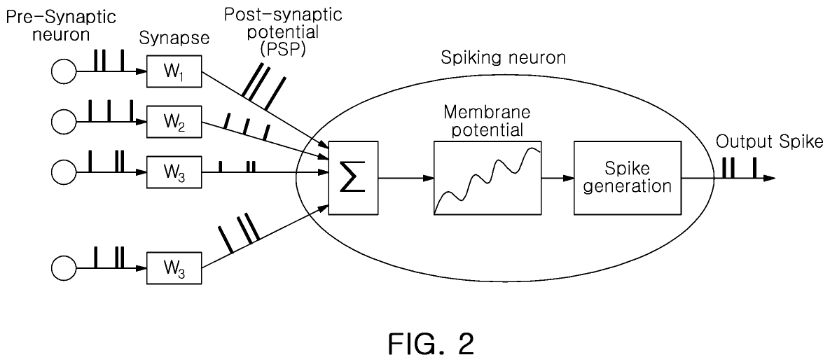

FIG. 2 is a view illustrating a spiking neuron of a SNN. An operating principle of the SNN is as follows: when a synapse receives an action potential, also known as a spike, from a pre-synaptic neuron, the synapse emits Post-synaptic potential (PSP). The PSP in turn stimulates a membrane potential of post-synaptic spiking neurons. A neuronal membrane potential exhibits temporal evolution that integrates the PSP. When the membrane potential exceeds a threshold voltage, the post-synaptic neurons are activated. In other words, an output spike is spiked. In the context of LIF neurons, the membrane potential u is determined by the equation:

$$τ \frac{du}{dt} = f ( u ) + \sum {w}_{i} {I}_{i} \qquad Equation 1$$

Here, f(u) is a leaky term that describes the leakage of charges accumulated in a nerve membrane, wᵢ is a synaptic weight, and Iᵢ is an input current varying depending on an excitatory or inhibitory PSP. When a voltage pulse of an excitatory input signal arrives, a membrane potential develops continuously over time, and when the voltage pulse exceeds a threshold voltage, a neural circuit transmits an output voltage pulse, thereby generating a spiking event. A FeFET-based spiking neurons represent a membrane potential (u) with an intrinsic state variable, and ferroelectric polarization.

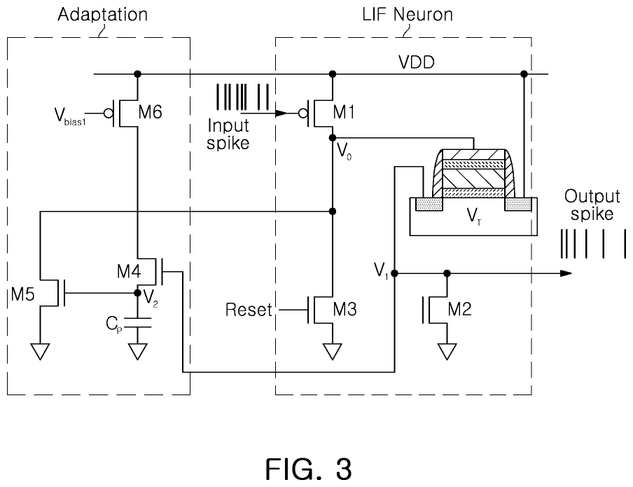

FIG. 3 is a view exemplarily illustrating a FeFET-based spiking neuron circuit. Referring to FIG. 3, an LIF neuron is implemented with one FeFET and three transistors M1 to M3. Additional transistors M4 to M6 assist in adaptation. As illustrated in FIG. 3, wherever input spikes are input to the transistor M1, a supply voltage VDD is applied to a gate of a FeFET neuron. A ferromagnetic material of FeFET is in a polycrystalline state and formed of a plurality of domains. Wherever the input spikes are input, a polarization state of a portion of the ferromagnetic domain changes. Accordingly, the threshold voltage of the FeFET neuron may be lowered. When the threshold voltage is sufficiently low and the FeFET neuron is turned on, a spike is output in the form of voltage through a load transistor M2. The spiking is performed with the spike output and the polarization of the FeFET neuron is restored using the transistor M3, thereby increasing the threshold voltage.

An input spike (e.g., PSP) is applied to a transistor M1. The transistor M1 may be a p-channel metal-oxide semiconductor (PMOS) transistor. Initially, both node voltages V₀ and V₁ are 0V. As the input spike is applied, the node voltage V₀ increases, a load voltage pulse is applied to the gate of the FeFET. When continuous pulses are applied, the FeFET suddenly changes from a high threshold voltage (V_{T}) state to a low threshold voltage (V_{T}) state and drain current Ip increases. Accordingly, an output spike is output and a node voltage V₁ increases. When the output spike is generated, a reset signal is applied to the transistor M3. As the transistor M1 is blocked during an interval between one spike and the other spike, the node voltage V₀ is pulled down to 0V. This causes a negative gate-source voltage (VGS) across the FeFET, the polarization is switched in an opposite direction and the FeFET is reset to a high threshold voltage (V_{T}) state.

Additionally, additional transistors M4 to M6 regulate an activity of an artificial neuron, and performs a bio-inspired adaptive mechanism that reduce a firing rate after all output spikes. A capacitor C_{P} is a parasitic capacitor of a corresponding node. During an event of all output spikes, when the node voltage V₁ increases, the transistor M4 is turned on, which in turn increases the node voltage V₂. Discharge velocity of the node voltage V₂ may be controlled by adding additional transistors. With an increase in the node voltage V₂, the transistor M5 is gradually turned on whenever an output spike occurs. Accordingly, the discharge velocity of the node voltage V₀ increases.

The neuromorphic computing device according to an embodiment of the present disclosure may include an FeFET/FeMBCFET synapse array, artificial neurons that receive excitatory and inhibitory synapses, or a layer buffer for flexible neuron configuration. The neuromorphic computing device may increase model flexibility by enabling the connection of excitatory and inhibitory synapses. Additionally, the neuromorphic computing device may increase model flexibility by improving the method of adjusting the neuron firing rate. Furthermore, the neuromorphic computing device may reduce chip area through 3D stacking. Also, the neuromorphic computing device of the present disclosure may increase model flexibility with flexible neuron configuration.

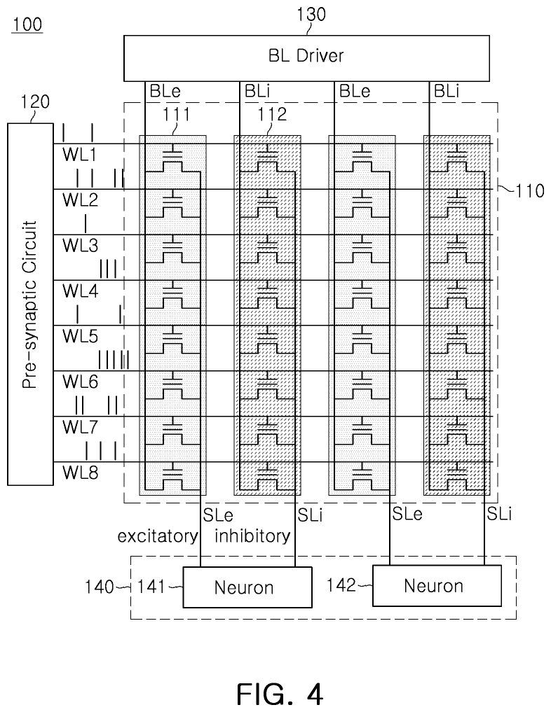

FIG. 4 is a view illustrating a neuromorphic computing device 100 according to an example embodiment of the present disclosure. Referring to FIG. 4, the neuromorphic computing device 100 may include a synapse array 110, a pre-synaptic neuron circuit 120, a bitline driver 130, and a spiking neuron circuit 140.

The synapse array may include at least one first string 111 (‘excitatory synapse’) and at least one second string 112 (‘inhibitory synapse’). The first string 111 may include a plurality of first ferroelectric transistors connected to an excitatory bitline BLe and an excitatory source line SLe. Each of the first ferroelectric transistors may include a gate connected to the wordlines WL1 to WL8. Each of the wordlines WL1 to WL8 may deliver an input spike. Also, the number of wordlines illustrated in FIG. 4 is 8 are exemplary, and it should be understood that the present disclosure is not limited thereto. The second string 112 may include a plurality of second ferroelectric transistors connected to an inhibitory bitline BLi and an inhibitory source line SLe. Each of the second ferroelectric transistors may include a gate connected to the wordlines WL1 to WL8. Each of the wordlines WL1 to WL8 may deliver the input spike. In an example embodiment, the synapse array may include excitatory synapses and inhibitory synapses arranged in a two-dimensional structure. In an example embodiment, the synapse array may include excitatory synapses and inhibitory synapses alternately arranged in a three-dimensional structure.

The pre-synaptic neuron circuit 120 may be configured to generate input spikes corresponding to data, and deliver the input spikes to each of the corresponding wordlines WL1 to WL8.

The bitline driver 130 may be implemented to provide corresponding bitline voltages to the excitatory bitline BLe and the inhibitory bitline BLi. In some example embodiments, the bitline voltages may be different from or identical to each other.

The spiking neuron circuit 140 may include a plurality of artificial neurons. Each of the artificial neurons receives an excitatory signal from the excitatory source line SLe connected to a first string (e.g., first string 111), and receives an inhibitory signal from an inhibitory source line SLi connected to a second string (e.g., second string 112), thereby outputting an output spike by performing an LIF operation on the excitatory signal and the inhibitory signal.

The neuromorphic computing device 100 according to an example embodiment of the present disclosure may include a FeFET-based synapse array 110 and artificial neurons. Here, the FeFET-based synapse array 110 may arrange an excitatory synapse column (e.g., first string 111) and an inhibitory synapse column (e.g., second string 112) in pairs, and may allow the corresponding artificial neuron to process each pair.

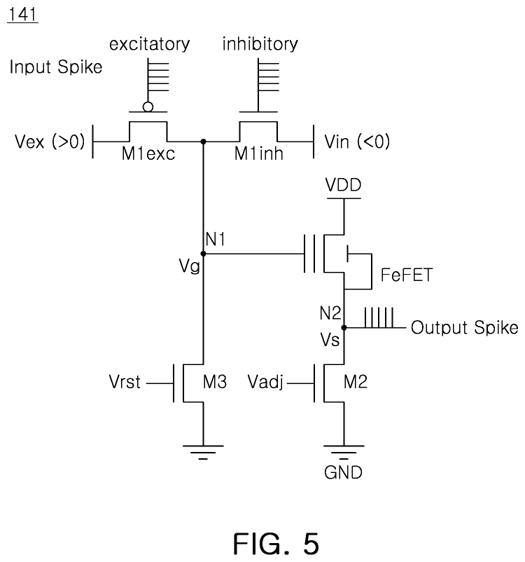

FIG. 5 is a view illustrating an artificial neuron 141 according to an example embodiment of the present disclosure. Referring to FIG. 5, the artificial neuron 141 may include a first input transistor M1exc, a second input transistor M1inh, an adjustment transistor M2, a reset transistor M3, and a ferroelectric transistor FeFET.

The first input transistor M1exc may be connected between a first node N1 and a first power terminal. The first power terminal may receive a first input power supply voltage Vex. Here, the first input power supply voltage Vex may be greater than 0V. The first input transistor M1exc may include a gate configured to receive an excitatory signal. In an example embodiment, the first input transistor M1exc may be implemented as a P-type transistor.

The second input transistor M1inh may be connected between the first node N1 and a second power terminal. The second power terminal may receive a second input power supply voltage Vin. Here, the second input power supply voltage Vin may be less than 0V. The second input transistor M1inh may include a gate configured to receive an inhibitory signal. In an example embodiment, the second input transistor M1inh may be implemented as an N-type transistor.

The adjustment transistor M2 may be connected between a second node N2 and a ground terminal GND. The adjustment transistor M2 may include a gate configured to receive an adjustment voltage Vadj.

The reset transistor M3 may be connected between the first node N1 and the ground terminal GND. The reset transistor M3 may include a gate configured to receive a reset voltage Vrst.

The ferroelectric transistor FeFET may be connected between a power terminal VDD and the second node N2. The ferroelectric transistor FeFET may include a gate connected to the first node N1 configured to receive a gate voltage Vg. In an example embodiment, the ferroelectric transistor FeFET may be implemented in a common source/well structure.

Also, the artificial neuron 141 illustrated in FIG. 5 is comprised of transistors configured to receive the excitatory signal from the excitatory synapse and to receive the inhibitory signal from the inhibitory synapse, respectively. However, it should be understood that the present disclosure is not limited thereto. It should be understood that the artificial neuron of the present disclosure may be implemented with a single transistor configured to receive both the excitatory signal and the inhibitory signal.

Generally, the excitatory synapse may promote spiking by increasing a membrane voltage of neurons, and the inhibitory synapse may suppress the spiking by lowering the membrane voltage of neurons. In this manner, a PMOS transistor in which the excitatory synapse is input in the artificial neuron 141 may be connected to a Vex power supply having a positive voltage, and a n-channel metal-oxide semiconductor (NMOS) transistor in which the inhibitory synapse is input may be connected to a Vin power supply having a negative voltage. In an embodiment, the spikes of the excitatory synapse decrease a threshold voltage of the ferroelectric transistor FeFET, and the spikes of the inhibitory synapses increase the threshold voltage of the ferroelectric transistor FeFET. When the threshold voltage is lower than a reference value, the spiking is performed (i.e. an output of the output spike), and when the threshold voltage is higher than the reference value, the spiking is not performed. The artificial neuron 141 may process the excitatory synapse and the inhibitory synapse in this manner.

casein an embodiment, a polarization change caused by the spikes is a result of a writing operation of the FeFET neuron. Conventional FeFET neurons adjust a firing rate by adjusting a power supply voltage VDD. The artificial neuron of the present disclosure may use a common source/well structure so that a channel voltage is equal to a source voltage, thereby lowering a write voltage. The artificial neuron of the present disclosure may adjust the firing rate using input power supply voltages Vex and Vin, using a gate voltage Vadj of the adjustment transistor M2, or using a gate voltage Vrst of the reset transistor M3.

The neuromorphic computing device 100 of the present disclosure may be implemented to separate and diversify a firing rate adjusting means of artificial neurons from the power supply voltage VDD. Also, the neuromorphic computing device 100 of the present disclosure may adjust the firing rate using first and second input power supply voltages, using a gate voltage of the adjustment transistor, or using a gate voltage of the reset transistor in conjunction with the power supply voltage VDD.

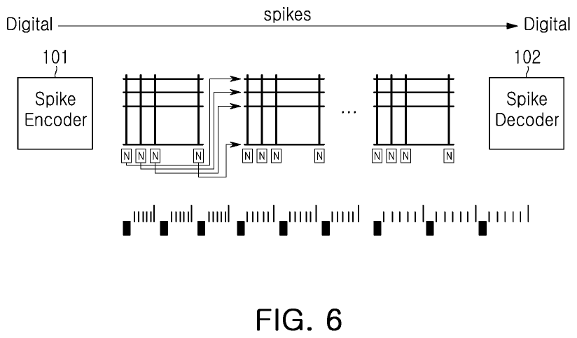

FIG. 6 is a view exemplarily illustrating a transmission process of spikes for each layer in a SNN. The neuromorphic computing device 100 may encode data into spikes by the spike encoder 101, may input train input spikes into a synaptic array, may receive the trained input spikes and output output spikes by artificial neurons, may repeat the output spike training, and may output data corresponding to the output spikes by the spike decoder 102.

The firing rate of artificial neurons is a significantly decisive control factor in the SNN. The SNN relies on the spiking of artificial neurons for each layer. The artificial neurons receive multiple spikes as input and output one spike. Accordingly, the frequency of output spikes is less when compared to that of input spikes. Accordingly, in artificial neurons of SNNs, the frequency of spikes decreases with each layer, which may reduce the amount of information transmitted.

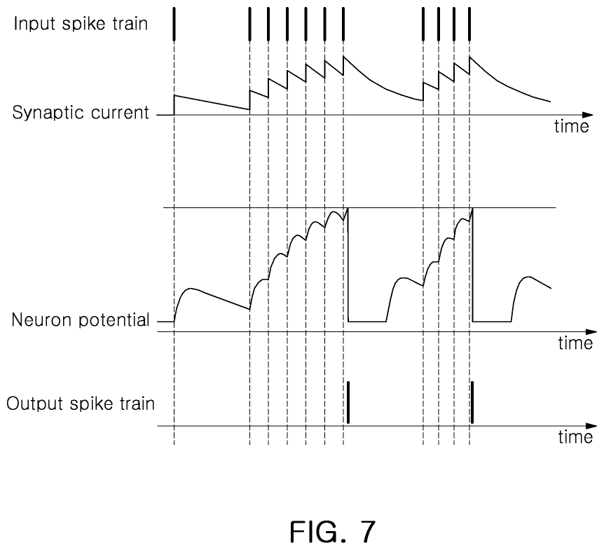

FIG. 7 is a view exemplarily illustrating a timing of obtaining an output spike by training an input spike in an SNN. As illustrated in FIG. 7, the synaptic current may increase depending on the training of the input spike. A potential of the artificial neuron also increases with the current. When the potential of the artificial neuron is equal to or more than a reference value, an output spike may be spiked.

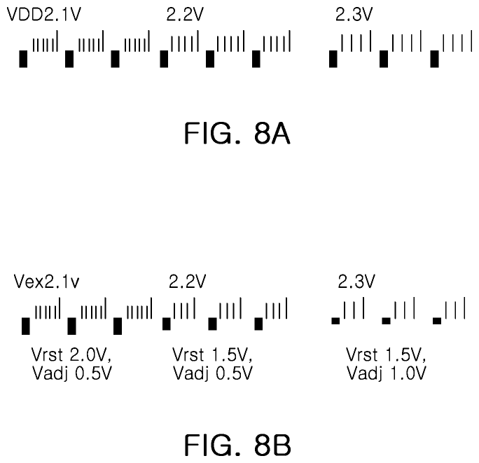

FIGS. 8A and 8B are views exemplarily illustrating a firing rate control method according to an example embodiment of the present disclosure. In the firing rate control method (VDD control method: 2.1→2.2→2.3) illustrated in FIG. 8A, the spiking frequency may be changed for each layer by increasing VDD, and the spiking frequency may decrease as the layer moves further. On the other hand, the firing rate control method illustrated in FIG. 8B (Vex/Vin control method: 2.1→2.2→2.3, Vrst control method: 2.0→1.5→1.5, and Vadj control method: 0.5→0.5→1.0) increases the spiking frequency for each layer as it moves further by adjusting Vex/Vin, Vrst, and/or Vadj. A plurality of spikes are required for data presentation. Accordingly, the artificial neuron of the present disclosure is advantageous here by having various means for controlling the spiking frequency.

Also, the synapse array according to an example embodiment of the present disclosure may be implemented in three dimensions.

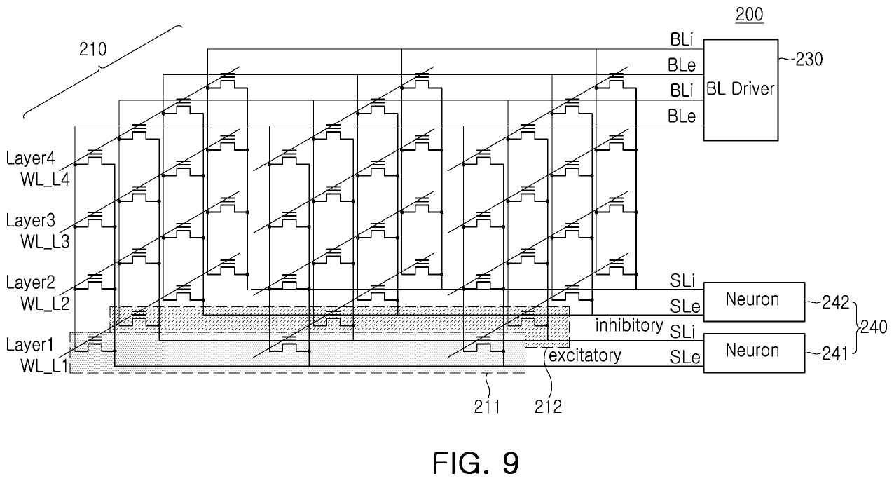

FIG. 9 is a view exemplarily illustrating a neuromorphic computing device according to another example embodiment of the present disclosure. Referring to FIG. 9, a neuromorphic computing device 200 may be implemented with a three-dimensional synapse array 210, a bitline driver 230, and a spiking neuron circuit 240.

The three-dimensional synapse array 210 has stacked layers. Each of the layers may include first cell transistors 211 connected between an excitatory bitline BLe and an excitatory source line SLe and second cell transistors 212 connected between an inhibitory bitline BLi and an inhibitory source line SLi. The first cell transistors 211 (‘excitatory synapse layer’) and the second cell transistors 212 (‘inhibitory synapse layer’) may be implemented as non-volatile memory transistors. For example, each of the first cell transistors 211 and the second cell transistors 212 may be implemented as ferroelectric transistors. Herein, the first cell transistors 211 and the second cell transistors 212 may include gates connected to corresponding wordlines among the wordlines WL_L1 to WL_L4 in the form of a substrate.

The spiking neuron circuit 240 may include artificial neurons 241 and 242. Each of the artificial neurons 241 and 242 may be implemented as an artificial neuron performing the LIF operation described in FIGS. 1 to 8.

In an example embodiment, the neuromorphic computing device 200 may further include a control logic configured to adjust the firing rate of the artificial neuron. In an example embodiment, the neuromorphic computing device 200 may further include a layer buffer including adjustment information for adjusting the firing rate of the artificial neuron with respect to each of the stacked layers. In an example embodiment, the cell transistor may be implemented as a Ferroelectric Multi-Bridge-Channel Field Effect Transistor (FeMBCFET).

The SNN goes through artificial neurons in each layer. casein the same or another embodiment, a pattern of input spikes is changed for each layer of the SNN. Accordingly, the spiking frequency of artificial neurons varies. When the spiking frequency is significantly high or significantly low, the rate needs to be adjusted for each layer. The neuromorphic computing device 100 according to an example embodiment of the present disclosure may be implemented to adjust the firing rate through Vex, Vin, Vrst, and Vadj.

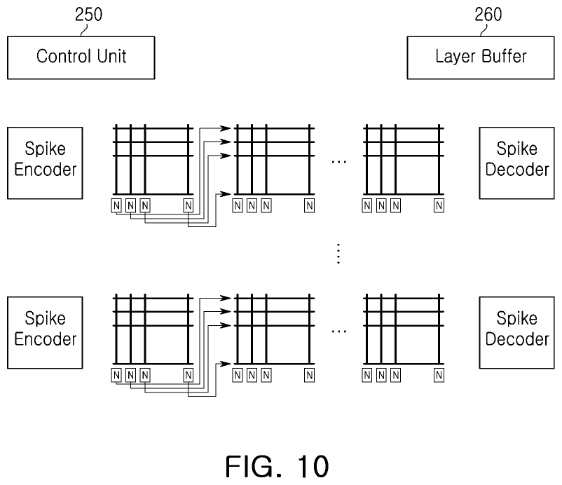

FIG. 10 is a view illustrating a flexible artificial neuron setting for each layer illustrating in FIG. 9. The neuromorphic computing device may encode data into spikes by spike encoders for each layer, may train input spikes by a synapse array for each layer, may receive the trained input spikes and output output spikes by artificial neurons for layer, may repeat an operation of training the output spikes for each layer, and may output data corresponding to the output spikes by a spike decoder for each layer.

Referring to FIG. 10, the neuromorphic computing device 200 may further include a control unit 250 and a layer buffer 260. The control unit 250 may be implemented to adjust the firing rate through Vex, Vin, Vrst, and Vadj. The layer buffer 260 may store Vex, Vin, Vrst, and Vadj values for each layer, and when a corresponding voltage is applied to neurons of each layer through the control unit 250, the layer buffer 260 may adjust the firing rate for each layer. In an example embodiment, the layer buffer 260 may be implemented as volatile/non-volatile memory.

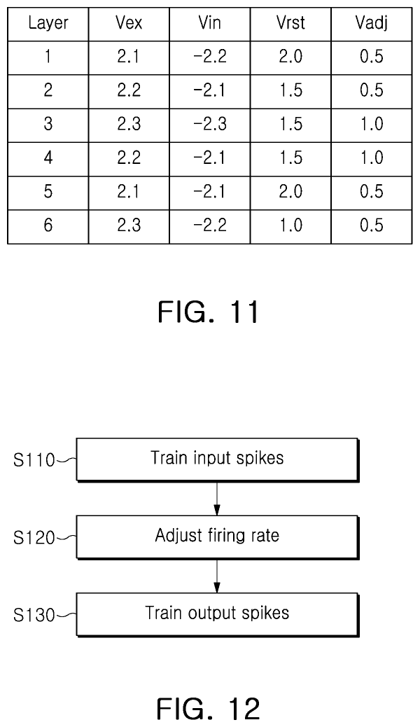

FIG. 11 is a view exemplarily illustrating flexible artificial neuron setting for each stacked layer. As illustrated in FIG. 11, Vex, Vin, Vrst, and Vadj may be set in each of the six layers. Also, the adjustment information for each layer may vary depending on environmental information of the neuromorphic computing device. Here, the environmental information may be a temperature, data throughput, data processing velocity, operating frequency, and the like, of the device.

The present disclosure relates to a FeFET synapse array and a FeFET neuron that may simultaneously process excitatory synapse and inhibitory synapse. The present disclosure further relates to a FeMBCFET-based 3D synapse array and a flexible neuron setting method of adjusting the firing rate for each layer.

FIG. 12 is a flowchart illustrating an operation of a neuromorphic computing device according to an example embodiment of the present disclosure. Referring to FIGS. 1 to 12, an operation of a neuromorphic computing device having artificial neurons connected to excitatory synapses and inhibitory synapses may proceed as follows. The neuromorphic computing device may train input spikes of artificial neurons through excitatory synapses and the inhibitory synapses (S110). The neuromorphic computing device may adjust the firing rate of artificial neurons in various ways (S120). For example, the neuromorphic computing device may adjust at least one of a power supply voltage, a first input power supply voltage, a second input power supply voltage, an adjustment voltage, and a reset voltage, thereby adjusting the firing rate of the artificial neurons. The neuromorphic computing device may train output spikes of the artificial neurons according to the adjusted firing rate (S130).

In an example embodiment, each of the artificial neurons may include: a ferroelectric transistor having a gate connected to a first node and connected between a power terminal configured to receive a power supply voltage and a second node configured to output an output spike; a first input transistor having a gate configured to receive a first input spike from a corresponding excitatory synapse, and connected between a first input power terminal configured to receive a first input power supply voltage and the first node; a second input transistor having a gate configured to receive a second input spike from a corresponding inhibitory synapse, and connected between a second input power terminal configured to receive a second input power supply voltage and the first node; an adjustment transistor having a gate configured to receive an adjustment voltage and connected between the second node and a ground terminal; and a reset transistor having a gate configured to receive a reset voltage, and connected between the first node and the ground terminal.

In an example embodiment, the neuromorphic computing device may generate input spikes corresponding to digital data, and may output digital data corresponding to each of the output spikes. In an example embodiment, excitatory synapses and inhibitory synapses may be implemented with three-dimensionally stacked Ferroelectric Multi-Bridge-Channel Field Effect Transistor (FeMBCFET).

Also, artificial neurons according to example embodiments of the present disclosure may be used in spiking neural networks.

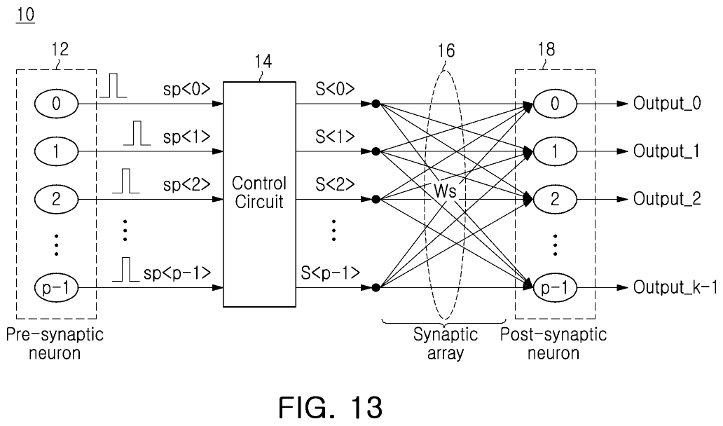

FIG. 13 is a schematic view illustrating a spiking neural network according to an example embodiment of the present disclosure. Referring to FIG. 13, the spiking neural network 10 may be modeled as a pre-synaptic neuron 12, a control circuit 14, a synaptic array 16, and a post-synaptic neuron 18.

The pre-synaptic neuron 12 generates input spikes sp<j> (where j is an integer greater than or equal to 0). The pre-synaptic neurons 12 may also be post-synaptic neurons of previous layers in a multilayer spiking neural network (SNN).

The control circuit 14 converts input spikes sp<j> generated simultaneously and multiple into a string selection signal S<j> (where j is an integer greater than or equal to 0). That is, the control circuit 12 converts input spikes (sp<j>) generated simultaneously multiple through several input channels into a string selection signal S<j> of an address corresponding to a corresponding channel. The control circuit 12 may generate the string selection signal S<j> in which a pulse width thereof is converted in response to one input spike sp<j>. That is, the control circuit 12 generates a string selection signal S<j> having a pulse width capable of reading all memory cells of one NAND cell string. Accordingly, the pulse width of the string selection signal S<j> corresponds to the time required to read one memory cell multiplied by the number (k) of memory cells included in the string. For example, it is assumed that in response to a first input spike, the control circuit 12 generates a string selection signal S<0>) that is activated during the string select time (A). Here, the string select time (A) may be the time required to sequentially read all memory cells included in one string.

The post-synaptic neuron 18 includes ‘k’ neurons for integrating synaptic weights Ws transmitted through the synapse array 16. The post-synaptic neuron 18 integrates currents reflecting the synaptic weight Ws provided by the synapse array 16 according to the ‘p’ number of string selection signals S<j>, and fires an output spike according to the integrated value. If ‘k’ neurons are included in the post-synaptic neuron 18, ‘k’ output spikes Output_0 to Output_k−1 may be generated simultaneously. When the spiking neural network 10 is formed of multiple layers, the post-synaptic neuron 18 may be considered a pre-synaptic neuron of subsequent layers.

The spiking neural network 10 of the present disclosure may use a memory element array of a non-volatile memory as a synapse element array. That is, the string selection signal S<j> generated in the control circuit 14 is a signal for selecting a string of a non-volatile memory, and the synapse array 16 for transmitting the synapse weights Ws may be implemented with data stored in each of the memory cells. Additionally, the post-synaptic neuron 18 may integrate the current transmitted according to the weights in a plurality of strings, and may be implemented with a plurality of sensing circuits generating output spikes depending on the amount of integrated currents.

In order to implement the above-described spiking neural network 10, vertically stacked three-dimensional non-volatile memory may be used. A spiking neural network 10 in which the synapse weight Ws may be easily expanded may be implemented with a high memory capacity.

Also, the neuromorphic computing device and the operating method thereof according to an example embodiment of the present disclosure may be implemented in an electronic device.

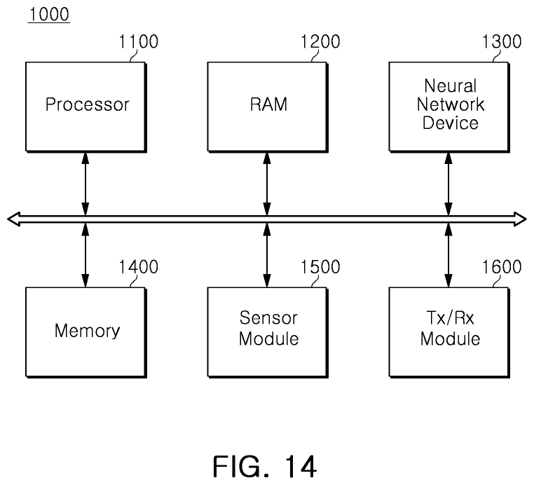

FIG. 14 is a view exemplarily illustrating an electronic device according to an example embodiment of the present disclosure. Referring to FIG. 14, an electronic device 1000 may extract valid information by analyzing input data in real time based on a neural network, and may determine a situation based on the extracted information or control the components of a device on which the electronic device 1000 is mounted. For example, the electronic device 1000 may be applied to robotic devices such as a drone, advanced driver assistance systems (ADAS), and the like, a smart TV, a smartphone, a medical device, a mobile device, a video display device, a measurement device, an IoT device, and the like, and may be mounted on at least one of various other types of devices.

The electronic device 1000 may include a processor 1100, a random access memory (RAM) 1200, a neural network device 1300, a memory device 1400, a sensor module 1500, and a communication device 1600. The electronic device 1000 may further include an input/output module, a security module, and a power control device. Some of the hardware components of the electronic device 1000 may be mounted on at least one semiconductor chip.

The processor 1100 may control an overall operation of the electronic device 1000. The processor 1100 may include one processor core (Single Core) or may include a plurality of processor cores (Multi-Core). The processor 1100 may process or execute programs or data stored in the memory device 1400. In some example embodiments, the processor 1100 may control the functions of the neural network device 1300 by executing programs stored in the memory device 1400. The processor 1100 may be implemented as a Central Processing Unit (CPU), Graphics Processing Unit (GPU), or Application Processor (AP).

The RAM 1200 may temporarily store programs, data, or instructions. For example, programs or data stored in the memory device 1400 may be temporarily stored in the RAM 1200 according to the control or booting code of the processor 1100. The RAM 1200 may be implemented as memory such as dynamic RAM (DRAM) or static RAM (SRAM).

The neural network device 1300 may perform a neural network calculation based on received input data, and may generate information signals based on performance results. The neural network may include CNN, RNN, FNN, a long short-term memory (LSTM), a stacked neural network (SNN), a state-space dynamic neural network (SSDNN), DBNdeep belief networks, and restricted Boltzmann machines (RBM), but the present disclosure is not limited thereto. The neural network device 1300 may be a neural network-specific hardware accelerator itself or a device including the same. The neural network device 1300 may perform read or write operations as well as neural network operations.

The neural network device 1300 may be implemented to perform neuromorphic computing described in FIGS. 1 to 13. Since the neural network device 1300 is able to implement weights having linear state change characteristics, the accuracy of neural network operations performed by the neural network device 1300 may be increased, and a more sophisticated neural network may be implemented.

An information signal may include one of various types of recognition signals, such as a voice recognition signal, an object recognition signal, an image recognition signal, and a biometric information recognition signal. For example, the neural network device 1300 may receive frame data included in a video stream as input data, and may generate a recognition signal for an object included in the image represented by the frame data from frame data. However, the present disclosure is not limited thereto, and the neural network device 1300 may receive various types of input data depending on the type or function of the device on which the electronic device 1000 is mounted, and may generate recognition signals according to input data.

The neural network device 1300 may perform, for example, a machine learning model such as linear regression, logistic regression, statistical clustering, Bayesian classification, decision trees, a principal component analysis or an expert system, or a machine learning model such as an ensemble technique such as a random forest. Such a machine learning model maybe used to provide, for example, various services such as an image classification service, a user authentication service based on biometric information or biometric data, an advanced driver assistance system (ADAS), a voice assistant service, and an automatic speech recognition (ASR) service.

The memory device 1400 is a storage location for storing data and may store an operating system (OS), various programs, and various data. In an example embodiment, the memory device 1400 may store intermediate results generated during the operation of the neural network device 1300.

The memory device 1400 may be a DRAM, but the present disclosure is not limited thereto. The memory device 1400 may include at least one of volatile memory or non-volatile memory. The non-volatile memory includes a Read Only Memory (ROM), a Programmable ROM (PROM), an Electrically Programmable ROM (EPROM), an Electrically Erasable and Programmable ROM (EEPROM), a flash memory, a Phase-change RAM (PRAM), a Magnetic RAM (MRAM), a Resistive RAM (RRAM), and a FRAM (Ferroelectric RAM). The volatile memory includes Dynamic RAM (DRAM), a Static RAM (SRAM), Synchronous DRAM (SDRAM), a Phase-change RAM (PRAM), a Magnetic RAM (MRAM), a Resistive RAM (RRAM), and a Ferroelectric RAM (FeRAM). In an example embodiment, the memory device 1400 may include at least one of a hard disk drive (HDD), a solid state drive (SSD), a compact flash (CF), a secure digital (SD), a micro secure digital (Micro-SD), a mini secure digital (Mini-SD), or a Memory Stick.

The sensor module 1500 may collect information around a device on which the electronic device 1000 is mounted. The sensor module 1500 may sense or receive signals (e.g., a video signal, an audio signal, a magnetic signal, a biometric signal, a touch signals, etc.) from the outside of the electronic device 1000, and may convert the sensed or received signal into data. To this end, the sensor module 1500 may include at least one of various types of sensing devices such as a microphone, an imaging device, an image sensor, a light detection and ranging (LIDAR) sensor, an ultrasonic sensor, an infrared sensor, a biosensor, and a touch sensor.

The sensor module 1500 may provide converted data to the neural network device 1300 as input data. For example, the sensor module 1500 may include an image sensor, and may capture an external environment of an electronic device 1000 to generate a video stream, and may sequentially provide successive data frames of the video stream as input data to the neural network device 1300. However, the present disclosure is not limited thereto, and the sensor module 1500 may provide various types of data to the neural network device 1300.

The communication device 1600 may be provided with various wired or wireless interfaces capable of communicating with external devices. For example, the communication device 1600 may include a communication interface capable of connecting to a mobile cellular network, such as a Wired Local Area Network (LAN), Wireless Local Area Network (WLAN) such as Wireless Fidelity (Wi-fi), Wireless Personal Area Network (WPAN) such as Bluetooth, Wireless USB (Wireless Universal Serial Bus), Zigbee, Near Field Communication (NFC), Radio-frequency identification (RFID), Power Line communication (PLC), or 3rd Generation (3G), 10th Generation (4G), and LTE (Long Term) Evolution.

The device described above may be implemented with hardware components, software components, or a combination of hardware components and software components. For example, the devices and components described in the example embodiments may be implemented using one or more general-purpose or special-purpose computers, like a processor, a controller, an arithmetic logic unit (ALU), a digital signal processor, a microcomputer, a field programmable gate array (FPGA), a programmable logic unit (PLU), a microprocessor, or any other devices capable of executing and responding to instructions. A processing device may execute an operating system (OS) and one or more software applications running on the operating system. Additionally, the processing device may access, store, manipulate, process, and generate data in response to the execution of software. For ease of understanding, a single processing device may be described as being used in some cases, but a person skilled in the art of the corresponding technical field will appreciate that the processing device may include a plurality of processing elements or a plurality of types of processing elements. For example, the processing device may include a plurality of processors or one processor and one controller. Additionally, other processing configurations, such as parallel processors, are possible.

The software may include a computer program, a code, instructions, or a combination of one or more thereof, and may configure the processing device to operate as desired or may command the processing device independently or collectively. In order be interpreted by or to provide instructions or data to the processing device, the software or data may be embodied in any type of machine, component, physical device, virtual equipment, computer storage medium, or device. The software may be distributed over networked computer systems, and may be stored or executed in a distributed manner. The software and data may be stored on one or more computer-readable recording media.

A neuromorphic computing device and operating method thereof according to an embodiment of the present disclosure may disclose an artificial neuron improved from existing FeFET neurons and a FeFET-based 2D synapse array, a FeMBCFET-based 3D synapse array, and a flexible neuron configuration method for adjusting the firing rate of artificial neurons for each layer.

The neuromorphic computing device may be implemented so that the artificial neuron receives both excitatory and inhibitory signals. The neuromorphic computing device may include a circuit for adjusting the fire rate of the artificial neuron. The neuromorphic computing device may be implemented with ferroelectric transistors of the MBCFET (Multi Bridge Channel FET; Nanosheet) structure. Meanwhile, the neuromorphic computing device may also be implemented with ferroelectric transistors of Planar FET structure, FinFET structure, GAA (Gate-All-Around) FET (Nanowire) structure, Forksheet structure, or CFET (Complementary FET) structure. A neuromorphic computing device and operating method thereof according to an embodiment of the present disclosure may increase model flexibility by enabling the connection of excitatory and inhibitory synapses. A neuromorphic computing device and operating method thereof according to an embodiment of the present disclosure may increase model flexibility by improving the method of adjusting the firing rate. A neuromorphic computing device and operating method thereof according to an embodiment of the present disclosure may reduce chip area through 3D stacking. Additionally, the neuromorphic computing device of the present disclosure may increase model flexibility with flexible neuron configuration.

Also, the contents of the present disclosure described above are only specific examples for carrying out the invention. The present disclosure will include not only concrete and practically usable means, but also technical ideas, which are abstract and conceptual ideas that may be used as technology in the future.

1. A neuromorphic computing device, the neuromorphic computing device comprising a plurality of artificial neurons connected to a synapse array,
wherein each of the plurality of artificial neurons comprises:
a ferroelectric transistor having a first gate connected to a first node, the ferroelectric transistor being connected between a power terminal configured to receive a power supply voltage and a second node configured to output an output spike;
a first input transistor having a second gate configured to receive a first input spike, the first input transistor being connected between a first input power terminal configured to receive a first input power supply voltage and the first node;
a second input transistor having a third gate configured to receive a second input spike, the second input transistor being connected between a second input power terminal configured to receive a second input power supply voltage and the first node;
an adjustment transistor having a fourth gate configured to receive an adjustment voltage, the adjustment transistor being connected between the second node and a ground terminal; and
a reset transistor having a fifth gate configured to receive a reset voltage, the reset transistor being connected between the first node and the ground terminal.

2. The neuromorphic computing device of claim 1,
wherein the first input spike is received from an excitatory synapse,
the second input spike is received from an inhibitory synapse.

3. The neuromorphic computing device of claim 1,
wherein the first input transistor comprises a P-channel Metal Oxide Semiconductor (PMOS) transistor, and
the second input transistor comprises an N-channel Metal-Oxide Semiconductor (NMOS) transistor.

4. The neuromorphic computing device of claim 1,
wherein the ferroelectric transistor is implemented to have a commonly connected a source and a well.

5. The neuromorphic computing device of claim 1,
wherein the first input power supply voltage is a positive voltage, and
the second input power supply voltage is a negative voltage.

6. The neuromorphic computing device of claim 1,
wherein a firing rate of an artificial neuron is adjusted by varying the power supply voltage.

7. The neuromorphic computing device of claim 1,
wherein a firing rate of an artificial neuron is adjusted by varying the first input power supply voltage, the second input power supply voltage, the adjustment voltage, or the reset voltage.

8. The neuromorphic computing device of claim 7, further comprising:
a control unit configured to adjust the firing rate.

9. The neuromorphic computing device of claim 1, wherein the synapse array is a two-dimensional structure comprising at least one excitatory synapse and at least one inhibitory synapse.

10. The neuromorphic computing device of claim 1, wherein the synapse array is a three-dimensional structure with stacked layers, wherein each layer comprises at least one excitatory synapse and at least one inhibitory synapse arranged alternately.

11. A neuromorphic computing device comprising:
a synapse array, wherein the synapse array comprises excitatory synapses having first ferroelectric transistors connected between excitatory bitlines and excitatory source lines, and inhibitory synapses having second ferroelectric transistors connected between inhibitory bitlines and inhibitory source lines are arranged alternately;
a pre-synaptic neuron circuit, wherein the pre-synaptic neuron circuit is connected to wordlines, and wherein the pre-synaptic neuron circuit is configured to provide corresponding input spikes to the wordlines, the wordlines being connected to gates of the first ferroelectric transistors and the second ferroelectric transistors;
a bitline driver configured to provide a first bitline voltage to the excitatory bitlines and to provide a second bitline voltage to the inhibitory bitlines; and
artificial neurons configured to:
receive an excitatory input spike from any one of the excitatory source lines,
receive an inhibitory input spike from any one of the inhibitory source lines, and
output an output spike by performing a Leaky Integration-and-Fire (LIF) operation.

12. The neuromorphic computing device of claim 11,
wherein the first bitline voltage and the second bitline voltage are different from each other.

13. The neuromorphic computing device of claim 11, further comprising:
a control unit configured to adjust a firing rate of each of the artificial neurons.

14. The neuromorphic computing device of claim 13,
wherein the wordlines are arranged in stacked layers, and
the control unit adjusts the firing rate associated with each of the stacked layers.

15. The neuromorphic computing device of claim 11,
wherein each of the artificial neurons comprises:
a ferroelectric transistor having a first gate connected to a first node, the ferroelectric transistor being connected between a power terminal configured to receive a power supply voltage and a second node configured to output an output spike;
a first input transistor having a second gate configured to receive a first input spike, the first input transistor being connected between a first input power terminal configured to receive a first input power supply voltage and the first node;
a second input transistor having a third gate configured to receive a second input spike, the second input transistor being connected between a second input power terminal configured to receive a second input power supply voltage and the first node;
an adjustment transistor having a fourth gate configured to receives an adjustment voltage, the adjustment transistor being connected between the second node and a ground terminal; and
a reset transistor having a fifth gate configured to receive a reset voltage, the reset transistor being connected between the first node and the ground terminal.

16-20. (canceled)

21. A neuromorphic computing device comprising:
a plurality of stacked layers comprising transistors, wherein each layer of the plurality of stacked layers comprises:
first ferroelectric transistors connected between an excitatory bitline and an excitatory source line, and
second ferroelectric transistors connected between an inhibiting bitline and an inhibiting source line;
a bitline driver configured to provide bitline voltages to the excitatory bitline and the inhibiting bitline; and
an artificial neuron connected to the excitatory source line and the inhibiting source line,
wherein the artificial neuron receives a first input spike through the excitatory source line and a second input spike received through the inhibiting source line, and
wherein the artificial neuron outputs an output spike by performing a Leaky Integration-and-Fire (LIF) operation.

22. The neuromorphic computing device of claim 21, further comprising:
a control unit configured to adjust a firing rate of the artificial neuron.

23. The neuromorphic computing device of claim 22, further comprising:
a layer buffer for adjusting the firing rate of the artificial neuron using adjustment information, wherein the adjustment information corresponds to respective layers in the plurality of stacked layers.

24. The neuromorphic computing device of claim 21,
wherein each transistor of the first ferroelectric transistors and the second ferroelectric transistors is implemented as a Ferroelectric Multi-Bridge-Channel Field Effect Transistor (FeMBCFET).

25. The neuromorphic computing device of claim 21,
wherein each transistor of the first ferroelectric transistors and the second ferroelectric transistors has a gate connected to a wordline substrate corresponding to respective layes of the plurality of stacked layers.
